(19) United States
(12) Patent Application Publication
(10) Pub. No.: US 2012/0204927 A1
(43) Pub. Date: Aug. 16, 2012

(54) Photovoltaic Shingle

(76) Inventors: George D. Peterson, Mt. Top, PA (US); Robert Bennett, Spotsylvania, VA (US)

(21) Appl. No.: 13/227,207

(22) Filed: Sep. 7, 2011

Related U.S. Application Data
(60) Provisional application No. 61/402,820, filed on Sep. 7, 2010.

(51) Int. Cl. H01L 31/042; H01L 31/0203

(52) U.S. Cl. 136/244; 136/259

(57) ABSTRACT

A photovoltaic shingle integrates a photovoltaic assembly within a roofing shingle. The shingle includes a first encapsulating material layer disposed on a substrate followed by the photovoltaic cell assembly and a second encapsulating material layer disposed on the photovoltaic assembly. A transparent superstrate such as a resin with polymer film is formed on the second encapsulating material layer. In one advantageous form, the photovoltaic shingle has at least two channels formed completely through the shingle in a stacking direction of the respective layers but only partially through in a direction perpendicular to the stacking direction thereby defining at least two tabs. In alternative forms, there may be additional channels such as but not limited to, two channels defining three tabs or five channels defining six tabs. The photovoltaic shingles may be arranged in an array to form a primary waterproof layer of a suitably pitched roof structure.

### CROSS REFERENCE TO RELATED APPLICATIONS

This application claims benefit of U.S. Provisional Application No. 61/402,820, filed Sep. 7, 2010 (which is hereby incorporated by reference). This application also relates to U.S. patent application Ser. No. 13/220,085, filed on Aug. 29, 2011; which claims the benefit of U.S. Provisional Application No. 61/402,233, both herein incorporated by reference.

### FIELD OF THE INVENTION

The present invention relates to a photovoltaic module and in particular a photovoltaic module incorporated into a photovoltaic shingle.

### BACKGROUND OF THE INVENTION

Electrical solar energy production is conventionally produced using photovoltaic cells. Typically the photovoltaic cells are arranged in an assembly which includes several photovoltaic cells. The assembly of photovoltaic cells are incorporated into a module. The modules, each comprising a number of photovoltaic cells, are joined together to form an array of photovoltaic modules. The photovoltaic modules typically each have a junction outside of the module between a positive conductor wire and a negative conductor wire which are connected to the photovoltaic assembly, i.e., one or more photovoltaic cells which comprise the photovoltaic module. The conductor wires are used for allowing the current to flow through the photovoltaic module from one module to the next module with the photovoltaic array.

Conventional arrays of photovoltaic modules are in the form of a panel of modules. The panel usually has a glass top surface or superstrate. In typical installations, the panels of photovoltaic cells are installed over conventional roofing material such as a commercial building roof or a asphalt shingled residential home.

One disadvantage with conventional photovoltaic panels are that they are seen by some as not being aesthetically pleasing to view. A second disadvantage is that conventional photovoltaic panels are heavy, due in part to the weight of the glass superstrate. For example, current building integrated photovoltaic (BIPV) roofing systems are considered by most to have poor aesthetics and are expensive and difficult to install, repair and upgrade. Further, since BIPV roofing systems are installed over existing roofing shingles, it is difficult to replace damaged roofing shingles as one must first remove the BIPV. In addition, ancillary components are expensive, require expertise in replacement, and involves potentially hazardous installation. In addition, current BIPV require specialized skilled installers resulting in a major cost of a typical BIPV system to be the cost of installation.

One recent photovoltaic solar material is disclosed in U.S. Pat. No. 5,990,414 (“the '414 patent”). The photovoltaic solar material comprises individual cells which are interconnected in a staggered pattern. However, the material must be installed over an existing shingled or otherwise waterproofed roof as the material itself does not form a waterproof surface over the roof. Therefore, although the material in the '414 patent may mimic a shingled roof, the material itself must be placed over a previously shingled or otherwise waterproof sealed roof.

What is needed in the art is a new and improved photovoltaic assembly in the form of a photovoltaic material which overcomes the weight problems associated with prior photovoltaic designs, and which provide for a single material which both replaces conventional shingles and produces solar energy.

### SUMMARY OF THE INVENTION

The present invention relates to a roof shingle which has an integrated photovoltaic module. The module includes a substrate and a photovoltaic cell assembly with encapsulated material above and below the assembly. The photovoltaic assembly has at least one photovoltaic cell. A positive output cable and a negative output cable are associated with the photovoltaic cell assembly and extend from an exterior surface of the photovoltaic shingle. A transparent superstrate preferably composed of a resin with polymer film, but may be made of any suitable material including glass, or exclusively a polymer film or resin.

In various advantageous forms, one or more channels are formed completely through a stacking direction of the layers which comprise the photovoltaic shingle, defining two or more tabs along a longer edge of the shingle, thereby producing a shingle having the appearance of a conventional two or more tab design. For example, two channels form a three tab shingle and five channels form a six tab shingle.

In further, alternative forms, the photovoltaic shingle includes a by-pass diode completely encapsulated within a photovoltaic cell assembly thus forming an integral photovoltaic by-pass diode junction within the photovoltaic shingle.

The present photovoltaic shingles can be installed using conventional roofing tools and by traditional roofing companies with only minimal instruction on how to lay the photovoltaic shingles on a roof. The photovoltaic shingles are electrically connected to one another to form an array of photovoltaic shingles which completely cover a roof while producing an appearance of a conventional shingled roof.

The present invention, in one form thereof, relates to a photovoltaic shingle comprising a substrate, a first encapsulated material disposed on the substrate and a photovoltaic cell assembly disposed on the first encapsulated layer. The photovoltaic cell assembly has at least one photovoltaic cell. The photovoltaic cell assembly is electrically associated with a positive output cable and a negative output cable. A second encapsulating layer is disposed on the photovoltaic cell and a transparent superstrate is formed on the second encapsulating material layer. The photovoltaic shingle has at least one channel completely through in a stacking direction of the respective layers and only partially through in a direction perpendicular to the stacking direction, thereby defining at least two tabs. In one further advantageous form, two channels are formed completely through the shingle in the stacking direction to thereby define three tabs.

The present invention, in another form thereof, relates to an array of photovoltaic shingles such as at least two photovoltaic shingles. Each shingle comprises a substrate, a first encapsulating material layer disposed on the substrate and a photovoltaic cell assembly formed on the first encapsulating material. The photovoltaic cell assembly has at least one photovoltaic cell. The photovoltaic cell assembly is electrically associated with a positive output cable and a negative output cable. A second encapsulating layer is disposed on the photovoltaic cell assembly. A transparent substrate is disposed on the second encapsulating layer. Each photovoltaic shingle has at least one channel completely formed therethrough in a stacking direction of the respective layers and only partially through in a direction perpendicular to the stacking direction, thereby defining at least two tabs. At least two by-pass diodes, one operatively associated with each of the photovoltaic shingles at a junction between the respective positive output cable and negative output cable. The photovoltaic shingles are electrically connected to each other wherein, upon failure of one of the photovoltaic cell assemblies of the photovoltaic shingles, electric current traverses the photovoltaic shingles, passing through the operable photovoltaic cell assemblies while by-passing the failed photovoltaic cell assemblies.

The present invention, in another form thereof, relates to a photovoltaic shingle having a substrate, a first encapsulating material layer disposed on the substrate, a first reinforcement material layer disposed on the first encapsulating material layer and a second encapsulating material layer disposed on the first reinforcement material layer. A second reinforcement material layer is disposed on the second encapsulating material layer. A photovoltaic cell assembly comprises at least one photovoltaic cell. The photovoltaic cell assembly is disposed on the second reinforcement material layer. The photovoltaic cell assembly has a positive conductive wire and a negative conductive wire extending therefrom. The positive conductor wire is electrically associated with a positive output electric cable at a positive output intersection and the negative conductor wire is electrically associated with a negative output cable at a negative output intersection. A by-pass diode extends in a plane of the photovoltaic assembly. The by-pass diode is at a junction between the positive output intersection and the negative output intersection selectively electrically joining the positive output cable with the negative output cable thereby by-passing the photovoltaic cell assembly. The by-pass diode is at least partially surrounded by encapsulating material to thereby completely encapsulate the diode and the junctions within an integral unit defined by the photovoltaic cell assembly and the encapsulating material. A third encapsulating material layer is disposed on the photovoltaic cell assembly and the by-pass diode. A transparent superstrate is formed on the third encapsulating material layer.

### BRIEF DESCRIPTION OF THE FIGURES

The same may be carried out into effect, reference is now made, by way of example only, to the accompanying drawings in which:

FIG. 1 is a perspective view of a exemplary building with a roof covered in photovoltaic shingles in accordance with the present invention;

FIG. 2 is a plan view of a photovoltaic shingle in accordance with the present invention;

FIG. 3 is a sectional view of the photovoltaic shingle taken along line 3-3 in FIG. 2;

FIG. 4 is an exploded view of the photovoltaic module of FIG. 2;

FIG. 5 is a partial sectional view of the photovoltaic shingle taken along line 5-5 of FIG. 2; and

FIG. 6 is a sectional view of an array of photovoltaic shingles, in accordance with another aspect of the present invention.

### DETAILED DESCRIPTION OF THE PREFERRED EMBODIMENTS

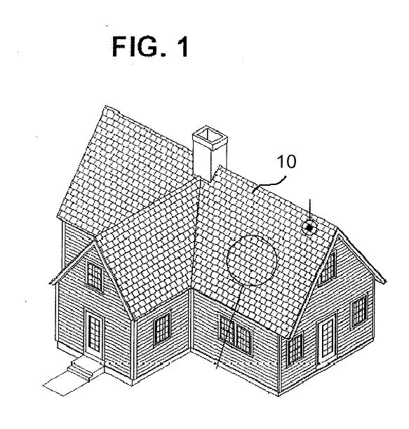

The present photovoltaic cell will now be described with reference to the drawings. FIG. 1 shows a exemplary structure which has a roof covered with photovoltaic shingles 10. As will be discussed further below, the shingles 10 include an integrated photovoltaic module. The individual photovoltaic shingles are connected together to form an array of photovoltaic shingles which, when installed, mimic the look of conventional shingles.

Solar energy is collected by encapsulated photovoltaic cells in the photovoltaic shingles 10 and converted into direct electric current (“DC current”). The photovoltaic cells are connected together on a single, three, or six, tab shingle to combine the solar energy delivered to the exposed surface of the shingle. The DC current is transferred to a junction by two electrical wires. In the junction, these wires are further sealed and insulated through encapsulation and connected to two output electrical wires. The output electrical wires are connected to adjacent shingles until the desired voltage and current is achieved. The shingle-to-shingle electrical connection is made with a flush butt connector sealed in thermal set polymer or with quick disconnects. After the shingle-to-shingle electrical connection is established, the output wires are connected to a device, such as an inverter or battery, to convert the generated electricity into a usable form. In the event of malfunction in the system, a built-in LED will indicate which shingle is not operating.

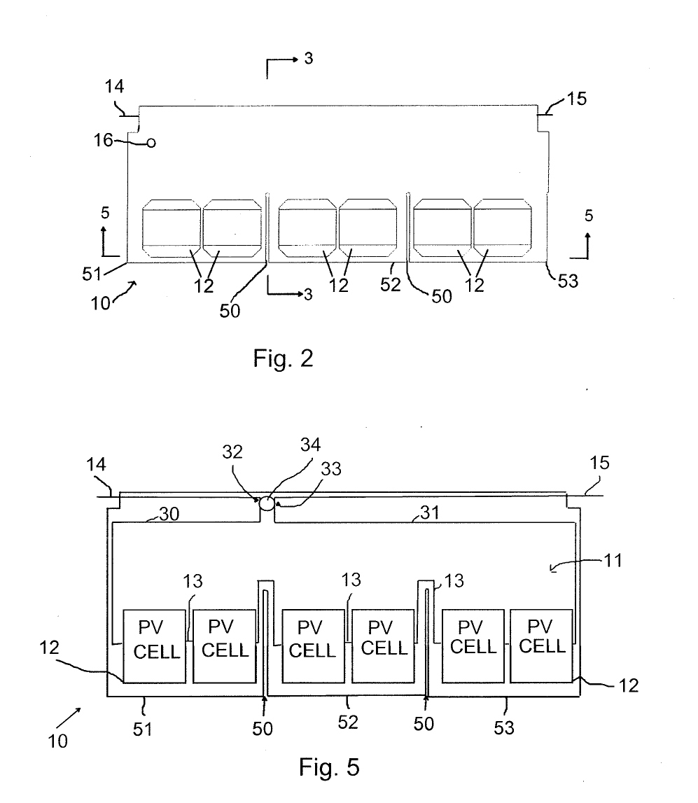

Referring to the photovoltaic shingle 10 in more detail, reference is made to FIGS. 2-5. The photovoltaic shingle 10 has a photovoltaic assembly 11 formed from a plurality of photovoltaic cells 12. Each of the photovoltaic cells 12 are electrically connected to one another via wires 13. Negative output cable 14 and positive output cable 15 extend from the photovoltaic shingle 10. An indicator sensor, such as indicator 16, illuminates to indicate a failure of the photovoltaic assembly 11. For example, failure of one or more of the photovoltaic cells 12 in the photovoltaic assembly 11 results in indicator light 16 illuminating. The photovoltaic cells 12 may be either crystalline cells or thin film cells.

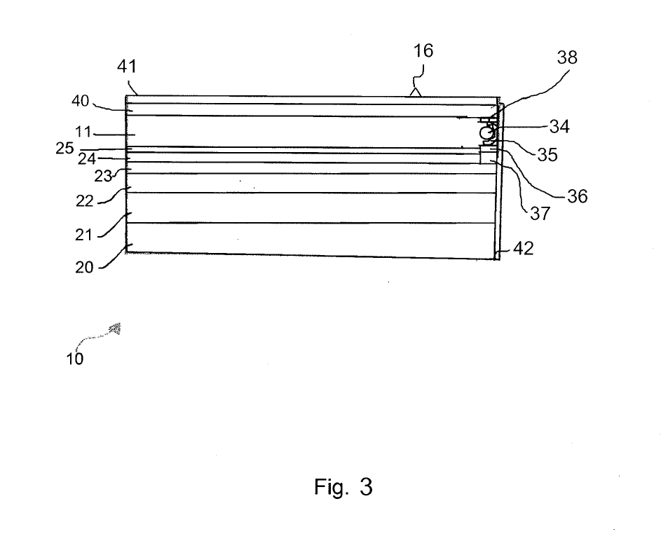

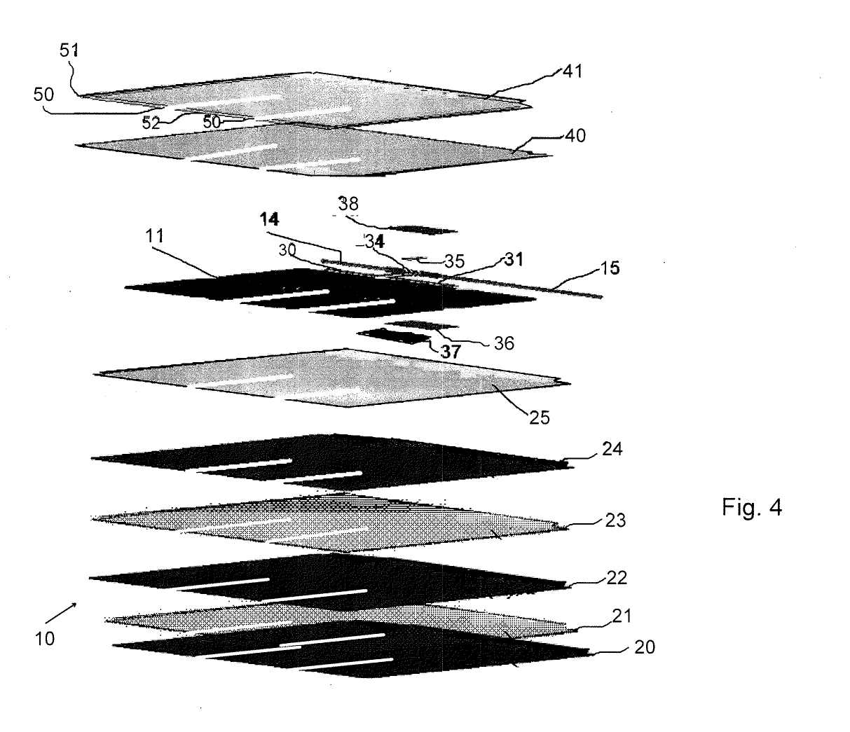

Referring now specifically to FIGS. 3 and 4 along with FIG. 5, the photovoltaic shingle 10 comprises a series of layers which form a single integral unit. The photovoltaic shingle 10 has a backsheet or substrate 20. The substrate 20 acts as a reinforcing substrate advantageously composed of a woven or mat fiberglass material which allows the photovoltaic shingle to be fastened to conventional roof sheeting with traditional roofing nails or hooks. The reinforcing substrate 20 is an electrically non-conductive material, such as fiberglass with a coefficient of expansion (the rate at which the materials expand or contract with temperature) compatible with the photovoltaic cells and a top layer of the photovoltaic shingle, i.e., a superstrate, to prevent delamination or separation of the layers which form the photovoltaic shingle 10. For example, a substrate mat may be composed of chopped fiberglass which forms a reinforcement mat.

A first encapsulating material layer 21, for example a sheet of a thermal setting polymer such as ethylene vinyl acetate (EVA) or polyvinyl pyrrolidon is applied over the entire area of the substrate 20. The material of the first encapsulating material layer 21 fully impregnates the woven or mat material of the substrate 20, when the photovoltaic shingle 10 is laminated during the manufacturing process (as will be described below), to thereby form a watertight barrier.

A first reinforcement material layer 22 is formed on the first encapsulating material 21. The reinforcement material layer 22 is composed of an electrically non-conductive polymer such as woven or chopped fiberglass. A second encapsulating material layer 23 is formed on the reinforcement material layer 22 and may be composed of the same material as the first encapsulating material 21.

A second reinforcement material layer 24 is disposed over a portion of the second encapsulating layer 23 (best shown in FIG. 3). A third encapsulating material layer 25 is only as wide as the reinforcement material layer 24 (see, e.g., FIG. 3). The encapsulating material layer 25 can be formed of the same material as the first encapsulating material layer 21.

The photovoltaic cell assembly 11 is disposed on the third encapsulating material layer 25. Negative conductor wire 30 and positive conductive wire 31 extend from the plane of the photovoltaic assembly 11. The negative conductor wire 30 is electrically connected to the negative output cable 14 and positive output cable 15 at the respective intersection 32, 33.

A by-pass diode 34 is connected to the negative output cable 14 and the positive output cable 15 at intersections 32, 33, respectively. A strip of EVA tape 35 is wrapper around the outside of the by-pass diode 34. A photovoltaic insulating sheet 36, e.g., an ionomer-based material, such as Dupont PV5316 or a piece of EVA material is placed below the by-pass diode 34 under EVA tape 35.

A bottom diode cover 37 and top diode cover 38 are placed, respectively, below and above the diode. The diode covers 37, 38 are composed of a semi-rigid nonconductive polymer. Optionally, an EVA patch may be placed immediately above and/or below the by-pass diode 34 covered with tape 35.

A full sheet of encapsulating material, a fourth encapsulating material layer 40, completely covers the photovoltaic assembly 11 and the top diode cover 38. A superstrate material 41 is placed over the fourth encapsulating material layer 40. The superstrate 41 can be composed of any suitable material. Advantageously the superstrate is a resin with a polymer film formed thereover. Alternatively, the superstrate 41 can be composed of glass, a polymer film, or resin, individually or in any combination.

A strip of tape, such as acrylic tape 42 is placed on a peripheral edge of the photovoltaic shingle 10, including a portion of the substrate 20 up to a portion of the superstrate 41.

It will now be apparent to one skilled in the art that the photovoltaic assembly 11 and by-pass diode 34 of the present photovoltaic shingle are completely encapsulated in a single integral unit. For example, the integral unit of the photovoltaic shingle 10 is defined by the various EVA layers and EVA tape 35, the encapsulating material of EVA 36, bottom diode cover 37 and top diode cover 38, fourth encapsulating material layer 40 and tape 42.

A plurality of channels 50 are formed completely through the photovoltaic shingle 10 in a stacking direction of the plurality of layers which comprise the photovoltaic shingle 10, but only partially through the photovoltaic shingle 10 in a direction perpendicular to the stacking direction. Although the photovoltaic shingle 10 has two channels 50 defining three tabs 51, 52 and 53, in alternative forms, the shingle may only have a single channel thereby defining two tabs or four more channels defining five or more tabs. For example, five channels define six tabs of a photovoltaic shingle.

Example of One Preferred Manufacturing Method

In a non-limiting advantageous manufacturing method, the photovoltaic shingle 10 is manufactured by laying out one or more of the photovoltaic cells 12 on a work surface. The negative conductor wire 30 and the positive conductor wire 31 are soldered to the negative output cable 14 and positive output cable 15 at intersections 32, 33, respectively. Next the by-pass diode 34 is soldered to the intersections 32, 33 at a respective junction. The EVA tape 35 is wrapped around the exterior surface of the by-pass diode 34 and the photovoltaic encapsulating sheet 36 is placed below the by-pass diode 34 covered with EVA tape 35. Heat is applied to melt the EVA tape 35. Next, if desirable EVA patches are placed above and below the diode followed by diode covers 37, 38. The bottom diode cover 37 is placed under the by-pass diode.

The photovoltaic assembly 11 with covered by-pass diode 34 is transmitted from the work surface to the backsheet or substrate 20 covered with the first encapsulating material layer 21, the reinforcement material layer 22, the second encapsulating material layer 23, the second reinforcement material layer 24 and the third encapsulating material layer 25.

In an alternative manufacturing method, if thin film photovoltaics are used rather than the crystalline photovoltaic cells of photovoltaic assembly 11, the second reinforcement material layer 24 and the third encapsulating material layer 25 may be eliminated.

After the photovoltaic assembly 11 is transferred to the layers on the substrate 20, the top diode cover 38 is positioned and the encapsulating material layer 40 is then placed over the photovoltaic assembly 11 and the diode cover 38 followed by the superstrate 41. In a lamination process, heat and pressure is applied to the photovoltaic shingle 10 to melt the encapsulating material layers to thereby form a watertight structure. Finally, the peripheral strip of tape 42 is applied to the perimeter of the photovoltaic shingle 10 along the perimeter adjacent the by-pass diode 26.

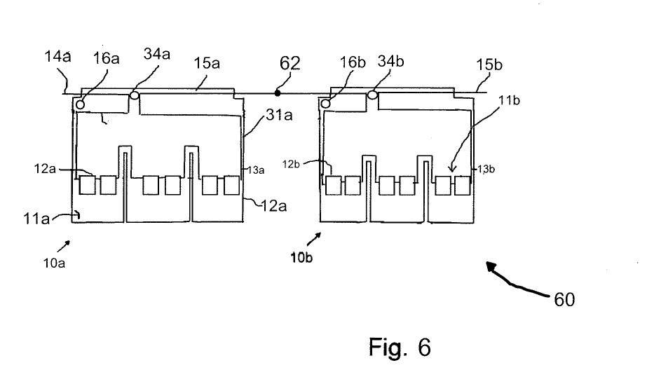

Referring now to FIG. 6, photovoltaic array 60 comprises a plurality of photovoltaic shingles 10a, 10b, depicted as two shingles to simplify the drawing of FIG. 6. Photovoltaic shingle 10a is electrically joined to photovoltaic module 10b at connection 62. Although FIG. 6 depicts just two photovoltaic shingles, the array may contain hundreds of photovoltaic shingles connected together.

During operation of the photovoltaic shingles 10a, 10b, electrical current flows from negative output electric cable 14a to negative conductor wire 30a, through the photovoltaic assembly 11a to the positive conductor wire 31a to the positive output cable 15a and then on to the photovoltaic shingle 10b. Upon failure of one of the photovoltaic shingles, for example photovoltaic assembly 11a, the by-pass diode 34a selectively joins the positive output cable 14a with the negative output cable 15a, thereby electrically bypassing the photovoltaic assembly 11a. As a result, current passes through the photovoltaic shingle 10a, bypassing the photovoltaic assembly 11a and continues on to the photovoltaic shingle 10b.

It will now be apparent to one of ordinary skill in the art that the present photovoltaic shingles which integrate a photovoltaic assembly within a shingle provides features and advantages over prior photovoltaic modules and solar panels which are installed over an existing shingled or waterproof roof. The present photovoltaic shingles can be installed by using conventional installation techniques using conventional roofing materials such as nails and shingle hooks by existing roofers. The photovoltaic shingles 10 have the appearance of a traditional roofing material and thus architecturally are aesthetically pleasing. Further, each individual photovoltaic shingle can be individually replaced if one fails without having to remove an entire solar panel. In addition, should an individual module need to be replaced due to weathering, unlike traditional solar panels placed over a roof in which the solar panel must be removed prior to removing a damaged shingle, since the photovoltaic assembly is integrated within the shingle, one needs to only replace the damaged shingle.

Although the invention has been described above in relation to preferred embodiments thereof, it will be understood by those skilled in the art that variations and modifications can be effected in these preferred embodiments without departing from the scope and spirit of the invention.

1. A photovoltaic shingle, comprising:
a substrate;
a first encapsulating material layer disposed on the substrate;
a photovoltaic cell assembly comprising at least one photovoltaic cell, the photovoltaic cell assembly disposed on the first encapsulating material layer, the photovoltaic cell assembly electrically associated with a positive output cable and a negative output cable;
a second encapsulating material layer disposed on the photovoltaic cell assembly; and
a transparent superstrate on the second encapsulating material layer,
wherein the photovoltaic shingle has at least one channel formed completely therethrough in a stacking direction of the respective layers, and only partially through in a direction perpendicular to the stacking direction, thereby defining at least two tabs.

2. The photovoltaic shingle of claim 1, wherein the at least one channel comprises two channels completely through in the stacking direction, and only partially through in the direction perpendicular, thereby defining three tabs.

3. The photovoltaic shingle of claim 1, wherein the substrate is composed of fiberglass.

4. The photovoltaic shingle of claim 3, wherein the substrate is composed of woven fiberglass or a fiberglass mat.

5. The photovoltaic shingle of claim 1, wherein the encapsulating material is further comprising a thermal setting polymer.

6. The photovoltaic shingle of claim 5, wherein the polymer is ethylene vinyl acetate.

7. The photovoltaic shingle of claim 1, further comprising a first reinforcement material layer disposed on the first encapsulating material layer.

8. The photovoltaic shingle of claim 7, further comprising a third encapsulating material layer disposed on the first reinforcement material layer.

9. The photovoltaic shingle of claim 8, further comprising a second reinforcement material layer disposed on the third encapsulating material layer.

10. The photovoltaic shingle of claim 1, wherein the transparent layer is composed of a polymer.

11. The photovoltaic shingle of claim 10, wherein the transparent layer is a polymer film.

12. The photovoltaic shingle of claim 11, wherein the transparent layer is composed of glass.

13. The photovoltaic shingle of claim 11, wherein the transparent layer is composed of a resin.

14. The photovoltaic shingle of claim 1, wherein the photovoltaic cell assembly comprises:
a positive conductor wire electrically connecting the at least one photovoltaic cell to the positive output cable at a positive intersection;
a negative conductor wire electrically connecting the at least one photovoltaic cell to the negative output cable at a negative intersection; and
a by-pass diode extending in a plane of the photovoltaic cell assembly, the by-pass diode at a junction between the positive output intersection and the negative output intersection, selectively electrically joining the positive output cable with the negative output cable.

15. The photovoltaic shingle of claim 14, further comprising encapsulating material at least partially around the diode to thereby completely encapsulated via the diode and junctions within an integral unit defined by the photovoltaic assembly cell.

16. The photovoltaic shingle of claim 14, wherein the positive output cable and negative output cable extend from the integral unit.

17. The photovoltaic shingle of claim 1, further comprising a sensor for indicating the photovoltaic cell has failed.

18. The photovoltaic shingle of claim 1, wherein the photovoltaic cell assembly comprises at least two photovoltaic cells electrically connected to each other.

19. An array of photovoltaic shingles, comprising:
at least two photovoltaic shingles, each shingle comprising:
a substrate;
a first encapsulating material layer disposed on the substrate;
a photovoltaic cell assembly comprising at least one photovoltaic cell, the photovoltaic cell assembly disposed on the first encapsulating material layer, the photovoltaic cell assembly electrically associated with a positive output cable and a negative output cable;
a second encapsulating material layer disposed on the photovoltaic cell assembly; and
a transparent superstrate on the second encapsulating material layer, wherein each photovoltaic shingle has at least one channel completely formed therethrough in a stacking direction of the respective layers, and only partially through in a direction perpendicular to the stacking direction, thereby defining at least two tabs; and
at least two by-pass diodes, each one operatively associated with a respective one of the at least two photovoltaic shingles at a junction between the respective positive output cable and the negative output cable;
the at least two photovoltaic shingles being electrically connected to each other,
wherein, upon failure of one of the at least two photovoltaic cell assemblies of the at least two photovoltaic shingles, electrical current will traverse the at least two photovoltaic shingles by passing through an operable one of the photovoltaic cell assemblies while by-passing a failed photovoltaic cell assembly.

20. The array of photovoltaic shingles of claim 19, wherein the encapsulating material above the photovoltaic cell assembly is transparent.

21. The array of photovoltaic shingles of claim 19, further comprising a sensor for indicating the photovoltaic cell assembly has failed.

22. The array of photovoltaic shingles of claim 19, wherein the photovoltaic cell assembly comprises at least two photovoltaic cells electrically connected to each other.

23. A photovoltaic shingle, comprising:
a substrate;
a first encapsulating material layer disposed on the substrate;
a first reinforcement material layer disposed on the first encapsulating material layer;
a second encapsulating material layer disposed on the first reinforcement material layer;
a second reinforcement material layer disposed on the second encapsulating material layer;
a photovoltaic cell assembly comprising at least one photovoltaic cell, the photovoltaic cell assembly disposed on the second reinforcement material layer, the photovoltaic cell assembly having a positive conductor wire and a negative conductor wire extending therefrom, the positive conductor wire electrically associated with a positive output electric cable at a positive output intersection and the negative conductor wire electrically associated with a negative output cable at a negative output intersection;
a by-pass diode extending in a plane of the photovoltaic cell assembly, the by-pass diode at a junction between the positive output intersection and the negative output intersection, selectively electrically joining the positive output cable with the negative output cable, thereby by-passing the photovoltaic cell assembly, said by-pass diode being at least partially surrounded by encapsulating material to thereby completely encapsulated via the diode and the junctions within an integral unit defined by the photovoltaic assembly cell and the encapsulating material;
a third encapsulating material layer disposed on the photovoltaic cell assembly and the by-pass diode; and
a transparent superstrate on the third encapsulating material layer.

24. The photovoltaic shingle of claim 23, wherein the positive output cable and negative output cable extend from inside the integral unit to outside the integral unit.

25. The photovoltaic shingle of claim 23, wherein at least one channel is formed completely through the shingle in a stacking direction of the respective layers and only partially through the shingle in a direction perpendicular to the stacking direction, thereby defining at least two tabs.

26. The photovoltaic shingle of claim 25, wherein the at least one channel comprises two channels completely through in the stacking direction, and only partially through in the direction perpendicular, thereby defining three tabs.
